(19) United States
(12) Patent Application Publication
(10) Pub. No.: US 2021/0180952 A1
(43) Pub. Date: Jun. 17, 2021

(54) MICROELECTROMECHANICAL GYROSCOPE SYSTEM

(71) Applicant: National Applied Research Laboratories, Taipei (TW)

(72) Inventors: Yung-Fu Tsai, Hsinchu (TW); Yeong-Wei Wu, Hsinchu (TW); Min-Yu Hsieh, Hsinchu (TW); Kuo-Liang Wu, Hsinchu (TW); Ying-Wen Jan, Hsinchu (TW); Chen-Tsung Lin, Hsinchu (TW)

(73) Assignee: National Applied Research Laboratories, Taipei (TW)

(21) Appl. No.: 16/839,811

(22) Filed: Apr. 3, 2020

(30) Foreign Application Priority Data
Dec. 12, 2019 (TW) 108145548

(51) Int. Cl. G01C 19/5712; G01C 19/5776; G01C 19/5783; B81B 7/02; B81B 7/00

(52) U.S. Cl. CPC G01C 19/5712; G01C 19/5776; B81B 2201/0242; B81B 7/02; B81B 7/008; G01C 19/5783

(57) ABSTRACT

A microelectromechanical gyroscope system is provided. The system includes a first substrate, a second substrate, and a third substrate. The substrates respectively have a first fixing, a second fixing, and a third fixing surfaces. The system further includes a first sensing, a second sensing and a third sensing module boards respectively fixed to the fixing surfaces. Each sensing module board has several microelectromechanical gyroscopes. A signal processing control board is electrically connected to the first sensing module board, the second sensing module board, and the third sensing module board. Wherein the first substrate, the second substrate, and the third substrate are perpendicular to each other. With the above structure, on each system coordinate axis of the microelectromechanical gyroscope system, at least one gyroscope is aligned with it for data acquisition and measurement. Accordingly, the measurement accuracy of the system is improved.

### BACKGROUND OF THE INVENTION

### 1. Field of the Invention

The present invention relates to a microelectromechanical gyroscope system, and more particularly to a microelectromechanical gyroscope system having multiple sensing module boards.

### 2. Description of Related Art

With the rapid development of semiconductor technology, the sensors based on micro-electromechanical systems (MEMS) have been widely used in commercial and military applications. These sensors are characterized by their small size, low cost, and low power consumption. In the navigation and control of a flying vehicle, a gyroscope is an important sensing element for measuring azimuth or angle. However, the sensing precision of the MEMS gyroscope is low, which limits its applicability in high-precision navigation and control.

In order to solve the above-mentioned problem of low precision of a single MEMS gyroscope, please refer to FIG. 1. The conventional technology is to solder multiple MEMS gyroscopes 601 through the Surface Mount Technology (SMT) or the through-hole technology) on a printed circuit board 602. The multiple micro-electromechanical gyroscopes 601 forms a gyroscope array 603, and the printed circuit board 602 has a signal processor 604 for collecting sensor signals of the above gyroscopes. Then, through a cross calibration of the MEMS gyroscopes 601 and performing a signal filtering and synthesis by the signal processor 604, the noise can be greatly reduced so as to improve the sensing precision of the MEMS gyroscope system.

However, there are still some problems with the above-mentioned conventional techniques. Due to the structure of the gyroscope, each gyroscope has three measurement axes (respectively, a x axis, a y axis, and a z axis), and the three measurement axes are perpendicular to each other. For improving the measurement precision of the gyroscope, the three measurement axes of each gyroscope should be aligned with the system coordinate axes, that is, Rx, Ry, and Rz shown in FIG. 1. Accordingly, the signals and data measured by the measurement axes can precisely represent the motion state of the system. Wherein, the system coordinate axes Rx, Ry, Rz are perpendicular to each other to form a rectangular coordinate system. However, due to the circuit board manufacturing process, when the gyroscope 601 is soldered, the gyroscope 601 is placed flat on the printed circuit board 601, so that only the z axis of the measurement axis of the gyroscope is aligned with the system coordinate axis Rz, and the other measurement coordinate axes (x axis and y axis) may have deviation with respect to the system coordinate axes (Rx, Ry) as shown in FIG. 1. That is, in the three measurement axes of the gyroscope, only one of the measurement axes is aligned with the system coordinate axis, and the other axes may have deviation. As shown in FIG. 1, the x axis of the measurement axes of the gyroscope has a deviation with respect to the Rx axis of the system coordinate axis, and the y axis of the measurement axes of the gyroscope has a deviation with respect to the Ry axis of the system coordinate axis. Therefore, the signals and data measured by the x axis and y axis of the measurement axes cannot precisely represent the motion status of the system. Therefore, no matter the signal processor filter and compensate the signal, the measurement precision of the system cannot be improved further.

Therefore, how to solve the problem of low sensing precision of the conventional microelectromechanical gyroscope system in order to expand the application field of the microelectromechanical gyroscope system is a problem required to be solved.

### SUMMARY OF THE INVENTION

In order to solve the low sensing precision problem of the conventional microelectromechanical gyroscope system, the present invention provides a microelectromechanical gyroscope system, comprising: a first substrate, and the first substrate includes a first combination surface; a second substrate, and the second substrate includes a second combination surface; a third substrate, and the third substrate includes a first combination surface; a first sensing module board fixed to the first combination surface of the first substrate, and the first sensing module board includes multiple microelectromechanical gyroscopes and a first signal connection port; a second sensing module board fixed to the second combination surface of the second substrate, and the second sensing module board includes multiple microelectromechanical gyroscopes and a second signal connection port; a third sensing module board fixed to the third combination surface of the third substrate, and the third sensing module board includes multiple microelectromechanical gyroscopes and a third signal connection port; and a signal processing and control board electrically connected to the first sensing module board, the second sensing module board and the third sensing module board; wherein first substrate, the second substrate and the third substrate are perpendicular with each other; the first combination surface, the second combination surface and the third combination surface are also perpendicular with each other.

Wherein the first substrate, the second substrate, the third substrate form a coordinate system, and the coordinate system includes three system coordinate axes which are perpendicular with each other, as a X axis, a Y axis and a Z axis; each microelectromechanical gyroscope includes three measurement axes which are perpendicular with each other, as a x axis, a y axis and a z axis; wherein the z axis of the measurement axes of the microelectromechanical gyroscope on the first sensing module board can align with the Z axis of the system coordinate axes, the z axis of the measurement axes of the microelectromechanical gyroscope on the second sensing module board can align with the Y axis of the system coordinate axes, and the z axis of the measurement axes of the microelectromechanical gyroscope on the third sensing module board can align with the X axis of the system coordinate axes.

Wherein the signal processing and control board includes a first system connection port, a second system connection port, a third system connection port and a signal processor; the first system connection port electrically connects with the first signal connection port, the second system connection port electrically connects with the second signal connection port, and the third system connection port electrically connects with the third signal connection port.

Wherein the system connection ports and the signal connection ports are electrically connected through a cable way.

Wherein the system connection ports and the signal connection ports are electrically connected through a wireless way.

With the above structure, on each system coordinate axis of the microelectromechanical gyroscope system, at least one gyroscope is aligned with it for data acquisition and measurement. Accordingly, the measurement accuracy of the system is improved.

### BRIEF DESCRIPTION OF THE DRAWINGS

FIG. 1 is a schematic diagram of the microelectromechanical gyroscope system of the conventional art;

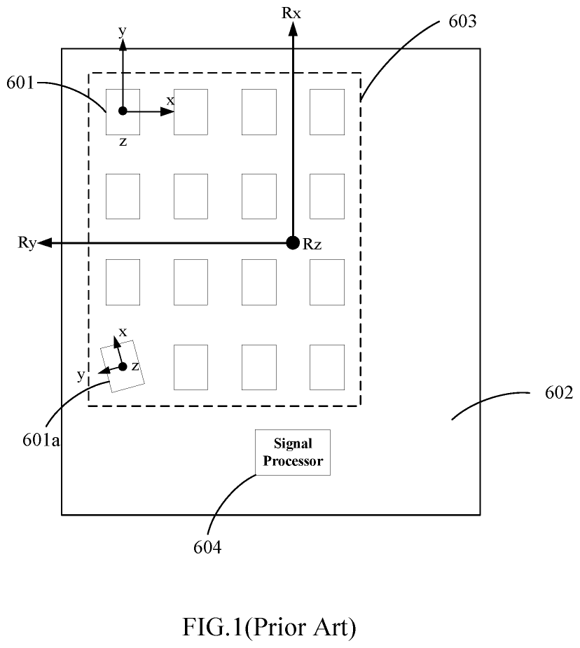

FIG. 2 is an exploded diagram of a microelectromechanical gyroscope system according to the present invention;

FIG. 3 is a schematic diagram of the microelectromechanical gyroscope system according to the present invention; and

FIG. 4 is a schematic diagram of a connection between the signal processing and control board and sensing module board according to the present invention.

### DETAILED DESCRIPTION OF THE PREFERRED EMBODIMENT

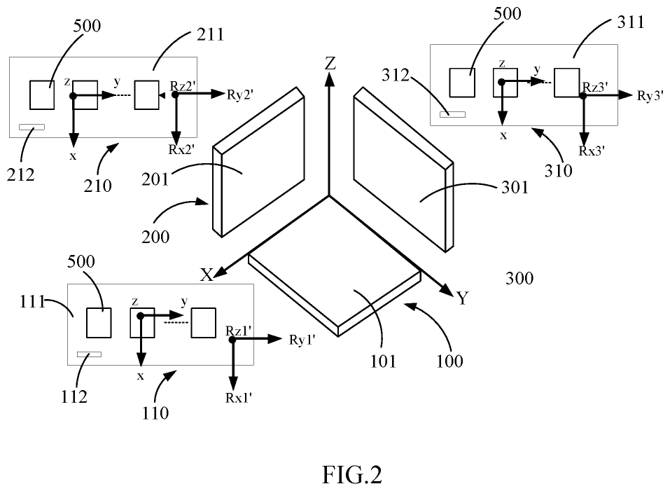

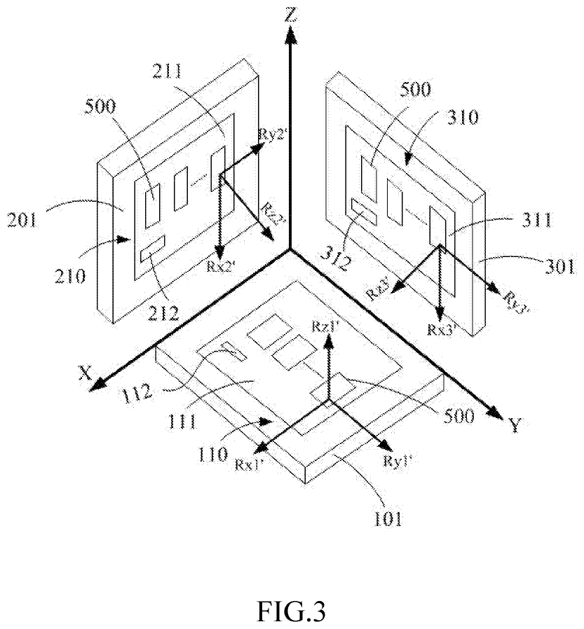

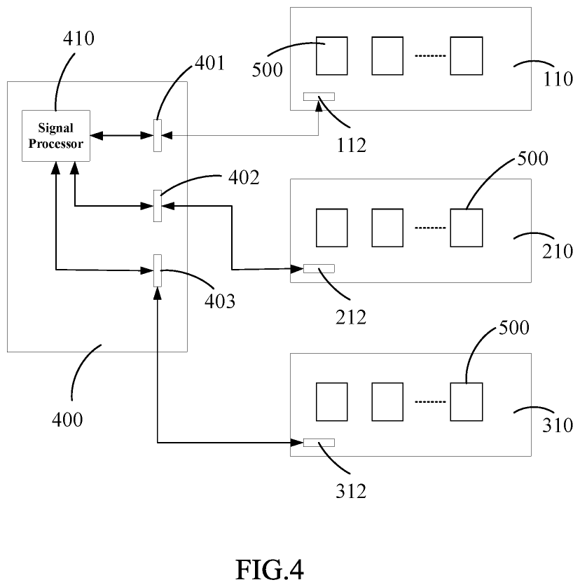

With reference to FIG. 2 and FIG. 3. FIG. 2 is an exploded diagram of the microelectromechanical gyroscope system of the present invention. FIG. 3 is a schematic diagram of the microelectromechanical gyroscope system of the present invention. The microelectromechanical gyroscope system of the present invention includes a first substrate 100, a second substrate 200, a third substrate 300, a first sensing module board 110, the second sensing module board 210, and the third sensing module board 310 and a signal processing and control board 400 (shown in FIG. 4). Wherein, the first substrate 100, the second substrate 200, the third substrate 300 are perpendicular with each other in order to form a coordinate system. The coordinate system includes three coordinate axes which are perpendicular with each other, as the X axis, the Y axis and the Z axis shown in FIG. 2. The first substrate 100 includes a first combination surface 101, the second substrate 200 includes a second combination surface 201, and the third substrate 300 includes a third combination surface 301. The first combination surface 101, the second combination surface 201 and the third combination surface 301 are also perpendicular with each other. The first sensing module board 110 includes a first assembly surface 111 and a first signal connection port 112. The second sensing module board 210 includes a second assembly surface 211 and a second signal connection port 212. The third sensing module board 310 includes a third assembly surface 311 and a third signal connection port 312.

Firstly, respectively disposing the multiple gyroscopes 500 on the first assembly surface 111 of the first sensing module board 110, the second assembly surface 211 of the second sensing module board 210 and the third assembly surface 311 of the third sensing module board 311. In other words, each of the sensing module boards 110, 210, 310 includes multiple gyroscopes 500. Then, using the conventional surface-mount technology or the through-hole technology to solder the multiple gyroscopes 500 on the first assembly surface 111 of the first sensing module board 110, the second assembly surface 211 of the second sensing module board 210 and the third assembly surface 311 of the third sensing module board 311. Accordingly, as description above, because of the assembly process of PCB and the function of the gravity, for sensing module boards 110, 210, 310, a z axis of measurement axis of the gyroscope 500 can align with module coordinate axes Rz1′, Rz2′ and Rz3′ of sensing module board better. As shown in FIG. 2, when manufacturing the first sensing module board 110, disposing the first sensing module board 110 to be flat, then, disposing the multiple gyroscopes 500 on the first assembly surface 111 of the first sensing module board 110. Accordingly, because of the feature of the PCB (Printed Circuit Board) process and the function of the gravity, the z axis of measurement axis of the gyroscope 500 on the first sensing module board 110 can align with the module coordinate axis Rz1′ of the first sensing module board 110 better. Similarly, the z axis of measurement axis of the gyroscope 500 on the second sensing module board 210 can align with the module coordinate axis Rz2′ of the second sensing module board 210 better, and the z axis of measurement axis of the gyroscope 500 on the third sensing module board 310 can align with the module coordinate axis Rz3′ of the third sensing module board 310 better.

Then, fixing the first sensing module board 110 to the first combination surface 101 of the first substrate 100, fixing the second sensing module board 210 to the second combination surface 201 of the second substrate 200 and fixing the third sensing module board 310 to the third combination surface 301 of the third substrate 300. Accordingly, the measurement precision of the system is greatly increased. The operation principle is described as following. When fixing the first sensing module board 110 to the first combination surface 101 of the first substrate 100, the module coordinate axis Rz1′ can align with the Z axis of the system coordinate axes. Because the z axis of the measurement axes of the gyroscope 500 is precisely aligned with the module coordinate axis Rz1′ of the first sensing module board 110, the z axis of measurement axes of the gyroscope 500 can align with the Z axis of the system coordinate axes precisely. Accordingly, using a signal measured by the gyroscope 500 on the first sensing module board 110 to represent a motion status of the microelectromechanical gyroscope system on the Z axis has a better precision degree.

Similarly, when fixing the second sensing module board 210 to the second combination surface 201 of the second substrate 200, the module coordinate axis Rz2′ can align with the Y axis of the system coordinate axes. Because the z axis of the measurement axes of the gyroscope 500 is precisely aligned with the module coordinate axis Rz2′ of the second sensing module board 210, the z axis of measurement axes of the gyroscope 500 can align with the Y axis of the system coordinate axes precisely. Accordingly, using a signal measured by the gyroscope 500 on the second sensing module board 210 to represent a motion status of the microelectromechanical gyroscope system on the Y axis has a better precision degree. Similarly, when fixing the third sensing module board 310 to the third combination surface 301 of the third substrate 300, the module coordinate axis Rz3′ can align with the X axis of the system coordinate axes. Because the z axis of the measurement axes of the gyroscope 500 is precisely aligned with the module coordinate axis Rz3′ of the third sensing module board 310, the z axis of measurement axes of the gyroscope 500 can align with the X axis of the system coordinate axes precisely. Accordingly, using a signal measured by the gyroscope 500 on the third sensing module board 310 to represent a motion status of the microelectromechanical gyroscope system on the X axis has a better precision degree.

Through the above way, each of the X axis, the Y axis and the Z axis of the microelectromechanical gyroscope system has a corresponding gyroscope 500 aligned with the axis to perform a measurement so that the measurement precision is higher than the conventional system.

With reference to FIG. 4, the signal processing and control board 400 includes a first system connection port 401, a second system connection port 402, a third system connection port 403 and a signal processor 410. The first system connection port 401 electrically connects with the first signal connection port 112. The second system connection port 402 electrically connects with the second signal connection port 212. The third system connection port 403 electrically connects with the third signal connection port 312. Through the above way, the high precision signals measured by the gyroscope 500 on each of the sensing module boards 110, 210, 310 can be transmitted to the signal processor 410 on the signal processing and control board 400. After collecting, filtering and synthesizing the above measured signals, the motion status in the space of the microelectromechanical gyroscope system can be obtained in order to obtain the physical quantity such as azimuth or angle. The electric connection way can be a cable way or a wireless way. The cable way can use a connector, or directly welding to connect the system connection port and the signal connection port. The wireless method can be a wireless protocol such as Wi-Fi or Bluetooth, and the present invention is not limited.

Besides, because the microelectromechanical gyroscope system of the present invention obtains the motion status of the microelectromechanical gyroscope system on the X axis, the Y axis and the Z axis using three sensing module boards and the signal processing and control board is disposed separately, when the measurement precision of the microelectromechanical gyroscope is improved because of improving in the manufacture process, replacing one of the three sensing module boards can improve the sensing precision of the coordinate axis corresponding to the sensing module board. Replacing entire printed circuit board including the multiple gyroscopes and the signal processor is not required so that the system upgrade is very flexible.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A microelectromechanical gyroscope system, comprising:
a first substrate, and the first substrate includes a first combination surface;
a second substrate, and the second substrate includes a second combination surface;
a third substrate, and the third substrate includes a first combination surface;
a first sensing module board fixed to the first combination surface of the first substrate, and the first sensing module board includes multiple microelectromechanical gyroscopes and a first signal connection port;
a second sensing module board fixed to the second combination surface of the second substrate, and the second sensing module board includes multiple microelectromechanical gyroscopes and a second signal connection port;
a third sensing module board fixed to the third combination surface of the third substrate, and the third sensing module board includes multiple microelectromechanical gyroscopes and a third signal connection port; and
a signal processing and control board electrically connected to the first sensing module board, the second sensing module board and the third sensing module board;
wherein first substrate, the second substrate and the third substrate are perpendicular with each other; the first combination surface, the second combination surface and the third combination surface are also perpendicular with each other.

2. The microelectromechanical gyroscope system according to claim 1, wherein the first substrate, the second substrate, the third substrate form a coordinate system, and the coordinate system includes three system coordinate axes which are perpendicular with each other, as a X axis, a Y axis and a Z axis;
each microelectromechanical gyroscope includes three measurement axes which are perpendicular with each other, as a x axis, a y axis and a z axis; wherein the z axis of the measurement axes of the microelectromechanical gyroscope on the first sensing module board can align with the Z axis of the system coordinate axes, the z axis of the measurement axes of the microelectromechanical gyroscope on the second sensing module board can align with the Y axis of the system coordinate axes, and the z axis of the measurement axes of the microelectromechanical gyroscope on the third sensing module board can align with the X axis of the system coordinate axes.

3. The microelectromechanical gyroscope system according to claim 2, wherein the signal processing and control board includes a first system connection port, a second system connection port, a third system connection port and a signal processor; the first system connection port electrically connects with the first signal connection port, the second system connection port electrically connects with the second signal connection port, and the third system connection port electrically connects with the third signal connection port.

4. The microelectromechanical gyroscope system according to claim 3, wherein the system connection ports and the signal connection ports are electrically connected through a cable way.

5. The microelectromechanical gyroscope system according to claim 3, wherein the system connection ports and the signal connection ports are electrically connected through a wireless way.
